(19) United States
(12) Patent Application Publication
(10) Pub. No.: US 2024/0413205 A1
(43) Pub. Date: Dec. 12, 2024

(54) GaN TRANSISTOR HAVING MULTI-THICKNESS FRONT BARRIER

(71) Applicant: Efficient Power Conversion Corporation, El Segundo, CA (US)

(72) Inventors: Robert Beach, La Crescenta, CA (US); Christopher Rutherglen, Rolling Hills Estates, CA (US); Robert Strittmatter, Tujunga, CA (US); Jianjun Cao, Torrance, CA (US); Alexander Lidow, Topanga, CA (US)

(73) Assignee: Efficient Power Conversion Corporation, El Segundo, CA (US)

(21) Appl. No.: 18/735,775

(22) Filed: Jun. 6, 2024

Related U.S. Application Data
(60) Provisional application No. 63/506,605, filed on Jun. 7, 2023.
(60) Provisional application No. 63/506,882, filed on Jun. 8, 2023.

(51) Int. Cl. H01L 29/06; H01L 29/20; H01L 29/778

(52) U.S. Cl. CPC H01L 29/0684; H01L 29/2003; H01L 29/7783; H01L 29/7787

(57) ABSTRACT

A gallium nitride (GaN) transistor which includes a multi-layer/multi-thickness barrier layer formed of segments of progressively increasing thickness between the gate and drain to progressively increase the 2DEG density in the channel from gate to drain. The GaN gate can be formed on the base barrier layer to produce an enhancement mode device with a positive threshold voltage. By forming the gate over a thicker segment of the barrier layer, a GaN transistor with a less positive threshold voltage, or a depletion mode transistor with a negative threshold voltage, can be produced.

The present application claims priority to U.S. Provisional Patent Application No. 63/506,605, filed on Jun. 7, 2024, and U.S. Provisional Patent Application No. 63/506,882, filed on Jun. 8, 2024, the entire disclosures of which are incorporated herein by reference.

### FIELD OF THE INVENTION

The present invention relates to column III nitride transistors such as gallium nitride (GaN) transistors. More particularly, the invention relates to GaN transistors having a multi-thickness front barrier.

### BACKGROUND OF THE INVENTION

GaN semiconductor devices are increasingly desirable for power semiconductor devices because of their ability to carry large current and support high voltages. Development of these devices has generally been aimed at high power/high frequency applications. Devices fabricated for these types of applications are based on general device structures that exhibit high electron mobility and are referred to as heterojunction field effect transistors (HFET), high electron mobility transistors (HEMT), or modulation doped field effect transistors (MODFET).

A GaN HEMT device includes a nitride semiconductor with nitride layers. Different materials formed on the semiconductor or on a buffer layer cause the layers to have different band gaps. The different crystallinity in the adjacent nitride layers also causes polarization, which contributes to a conductive two-dimensional electron gas (2DEG) region near the junction of the two layers, specifically in the layer with the narrower band gap. The nitride layers that cause polarization typically include a barrier layer and a buffer layer forming the 2DEG, which allows current to flow through the device. Because the 2DEG region exists under the gate at zero gate bias, traditional nitride devices are normally on, or depletion mode devices. If the 2DEG region is depleted below the gate at zero applied gate bias, the device is normally off and is an enhancement mode device.

FIG. 1 illustrates a cross-section of a prior art enhancement mode GaN transistor device more fully described in U.S. Pat. Nos. 8,350,294 and 8,404,508, issued to Lidow et al., the disclosures of which are herein incorporated by reference. GaN transistor 1 is formed on a substrate 10 that may comprise, for example, silicon Si, silicon carbide SiC or sapphire. Over and in contact with the substrate 10 are transition layers 12. Transition layers 12 comprise AlN or AlGaN, with a thickness of between 0.1 to 1.0 μm. A buffer layer 14 separates the transition layers 12 from a front barrier 16. The buffer layer 14 is preferably formed of GaN and has a thickness between 0.5 and 3 μm. The front barrier 16 is formed of AlGaN and has a thickness between 0.005 and 0.03 μm and an Al percentage of about 10% to 50%. Front barrier 16 has the same thickness across the entire device.

The different in crystallinity between the buffer layer 14 and the barrier layer 16 causes polarization, which forms a two-dimensional electron gas (2DEG) in a channel near the junction of the buffer layer 14 and the barrier layer 16, specifically in the buffer layer with the narrower band gap.

Source and drain contacts 18, 20 are disposed over the barrier layer 16. Source and drain contacts are formed of Ti or Al with a capping metal such as Ni and Au or Ti and TiN. A gate contact 24, formed of Ta, Ti, TiN, W, or WSi₂, and having a thickness of between 0.05 and 1.0 μm, is provided between the source and drain contacts. A gate material 26 is formed over the barrier layer 16 and under the gate contact 24. In a preferred embodiment of the invention, gate material 26 is a compensated gate material, i.e., GaN with a passivated p-type impurity such as, for example, Mg, Zn, Be, Cd, or Ca. The p-type doping of compensated gate material 26 results in an enhancement mode device. In addition, the insulating nature of compensated gate material 26 leads to low gate leakage and reduced gate capacitance during device operation.

A passivation/insulator layer 27 is provided over the barrier layer 16 between the source and drain contacts 18, 20 and extends over the p-type gate material 26 and the gate contact 24. In most silicon devices, the insulator/barrier interface is not a critical parameter. In GaN transistors, however, it is a critical parameter, dominating device performance. A single layer of a surface passivating insulator, such as passivation layer 27 in FIG. 1, can be made to minimize leakage current and gate to drain capacitance, or it can be made to give high electron density in the channel and low drain field. But the single insulating passivation layer cannot do both at the same time.

To address this issue, GaN transistor 2 may be provided with different surface passivation insulators 30, 32, 34, 36 disposed over the barrier layer 16 between the gate 22 and the drain contact 20, as shown in FIG. 2, and as described in U.S. Pat. No. 10,096,702, the disclosure of which is herein incorporated by reference. The different surface passivation insulators 30, 32, 34, 36 induce multiple segments of different densities of 2DEG 28 in the channel. As illustrated, the transistor 2 has four insulators 30, 32, 34, and 36 between the gate 22 and drain contact 20 with different densities that increases the 2DEG density 28 in the channel further away from the gate 22. Insulator 30 minimizes the gate leakage and fields near the gate that cause high gate-drain charge (Qgd). Insulator 36 minimizes electric fields at the drain contact and provides a high density of charge in the channel for low resistance. Insulators 32 and 34 provide a transition in the middle region between the gate and the drain. Insulators 30, 32, 34, and 36 can be formed of the same material, such as SiN, but with different process conditions and doping, such that insulator 30 produces a lower interface density of donor states than insulator 32, and insulator 34 provides a lower interface density of donor states than insulator 36.

An integrated circuit with both enhancement mode and depletion mode transistors having threshold voltages approximately equal in absolute value is disclosed in U.S. Pat. No. 9,583,480. It would desirable to obtain the advantages of that integrated circuit, in terms of adjusting the threshold voltage of a GaN transistor and providing the two types of GaN transistors (enhancement mode and depletion mode) in a single integrated circuit, while also obtaining the benefits of the graded 2DEG density of U.S. Pat. No. 10,096,702.

### SUMMARY OF THE INVENTION

The present invention in the various embodiments described below achieves the advantages discussed above, by providing a column III nitride transistor, preferably a GaN transistor which includes a multi-layer/multi-thickness barrier layer formed of segments of progressively increasing thickness between the gate and drain to progressively increase the 2DEG density in the channel from gate to drain. The GaN gate can be formed on the base barrier layer to produce an enhancement mode device with a positive threshold voltage. By forming the gate over a thicker segment of the barrier layer, a GaN transistor with a less positive threshold voltage, or a depletion mode transistor with a negative threshold voltage, can be produced.

More specifically, in the transistor of the present invention, the front barrier, formed of column III nitride materials, is provided in a multi-thickness laterally varying topology to induce a laterally varying 2DEG density underneath. In some embodiments, the multi-thickness of the barrier layer is obtained by a multi-layer barrier structure of alternating AlGaN and GaN layers that are etched at different lateral distances from the source. In other embodiments, the varying thickness of the barrier layer is obtained by forming a uniform AlGaN barrier layer in multiple thicknesses at different lateral distances from the source. The varying thickness of barrier layer advantageously provides the additional advantage of being able to customize the threshold voltage (V_{TH}) of the gate. An integrated circuit on a single substrate may be provided with transistors having different threshold voltages, including depletion mode transistors having negative threshold voltages, where the different gate threshold voltages are produced by forming the gate on barrier layers of different thicknesses.

Additional embodiments and additional features of embodiments for the GaN transistor and method for fabricating the GaN transistor of the present invention are described below and are hereby incorporated into this section.

### BRIEF DESCRIPTION OF THE DRAWINGS

The present application is further understood when read in conjunction with the appended drawings. For the purpose of illustrating the subject matter, there are shown in the drawings exemplary embodiments of the subject matter; however, the presently disclosed subject matter is not limited to the specific methods, devices, and systems disclosed. In the drawings:

FIG. 1 illustrates a cross-sectional view of a prior art enhancement mode GaN transistor.

FIG. 2 illustrates a cross-sectional view of the prior art enhancement mode GaN transistor of U.S. Pat. No. 10,096,702 with four different insulators over the barrier layer.

FIG. 3 illustrates a cross-sectional view of the enhancement mode GaN transistor according to a first embodiment of the present invention.

FIG. 4 illustrates a cross-sectional view of an enhancement mode GaN transistor according to a second embodiment of the present invention.

FIG. 5 illustrates a cross-sectional view of an enhancement mode GaN transistor according to a third embodiment of the present invention.

FIGS. 6-12 illustrates steps for a method of producing the enhancement mode GaN transistor of FIGS. 3-5.

FIG. 13 illustrates a cross-sectional view of a transistor according to a fourth embodiment of the present invention.

FIGS. 14-16 illustrate steps for a method of producing the GaN transistor of FIG. 13.

FIG. 17 illustrates a GaN transistor with a higher breakdown voltage than the transistor of FIG. 13.

Aspects of the disclosure will now be described in detail with reference to the drawings, wherein like reference numbers refer to like elements throughout, unless specified otherwise.

### DETAILED DESCRIPTION OF THE PREFERRED EMBODIMENTS

In the following detailed description, reference is made to certain embodiments. This detailed description is merely intended to teach a person of skill in the art further details for practicing preferred aspects of the present teachings and is not intended to limit the scope of the claims. Therefore, combinations of features disclosed in the following detailed description may not be necessary to practice the teachings in the broadest sense, and are instead taught merely to describe particularly representative examples of the present teachings. It is to be understood that other embodiments may be employed and that various structural, logical, and electrical changes may be made.

The present invention provides an enhancement mode GaN transistor with a front barrier of varying thickness. The front barrier of varying thickness can be a multi-layered front barrier formed of multiple AlGaN/GaN layers, where each AlGaN layer has a lower concentration of GaN than the immediately underlying GaN layer, or a single layer of AlGaN of varying thickness. The front barrier is etched to different thicknesses at varying distances from the source to create the varying thicknesses. Due to the varying thickness of the front barrier, the 2DEG at the underlying junction of the front barrier and the buffer has a corresponding varying electron density. Specifically, the front barrier is designed to have a varying thickness such that the 2DEG has a lower electron density near the gate to reduce gate leakage and gate damage, and a higher electron density near the drain to reduce the on-resistance of the transistor. The threshold voltage (V_{TH}) of the device can be customized based on the thickness of the front barrier on which the gate is formed. Specifically, the threshold voltage decreases if the gate is formed on a thicker segment of the front barrier.

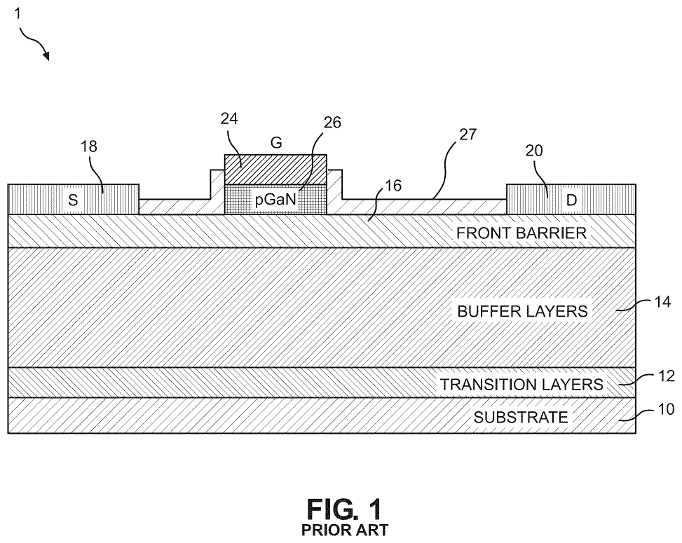

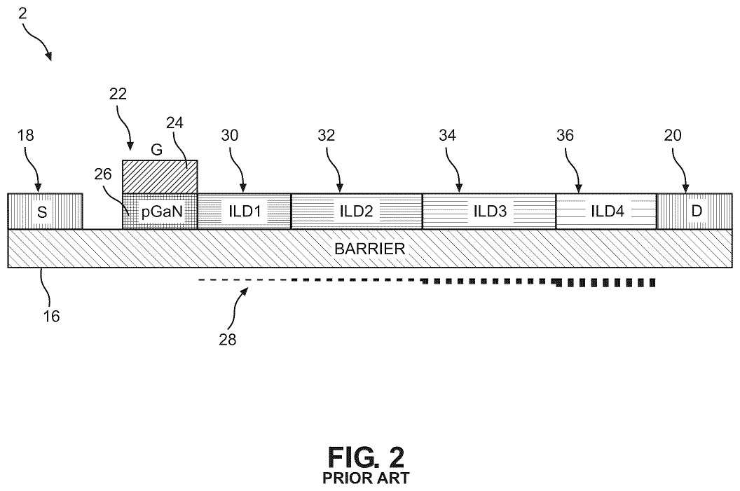

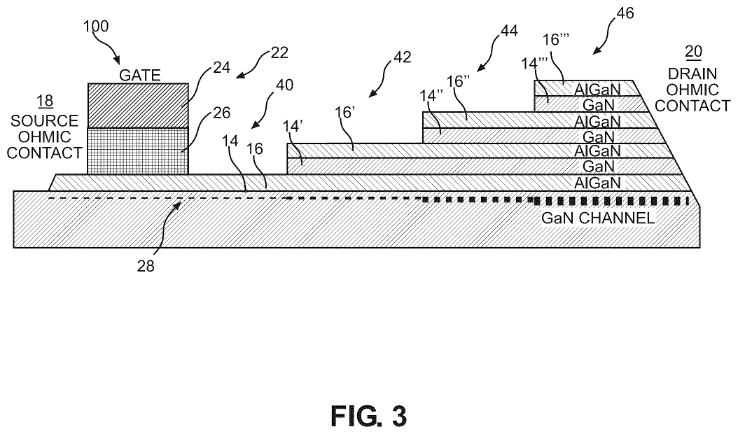

FIG. 3 illustrates a first embodiment of an enhancement mode GaN transistor 100 according to the present invention. GaN transistor 100 has a buffer layer 14 formed of GaN. Although not shown in FIG. 3, buffer layer 14 is formed over transition layers 12 layered on a substrate 10, as illustrated in FIG. 1. A first barrier layer 16 formed of AlGaN is deposited over the buffer layer 14, similar to FIG. 1. First barrier layer 16 has a substantially uniform thickness. As explained above, a conductive two-dimensional electron gas (2DEG) forms a channel near the junction of buffer layer 14 and first barrier layer 16, specifically at the top of buffer layer 14. Therefore, buffer layer 14 is referred to as the GaN channel layer.

As illustrated in FIG. 3, in accordance with the present invention, one or more pairs of GaN/AlGaN layers are layered over the AlGaN first barrier layer 16. Although pairs of GaN/AlGaN layers as shown in FIG. 3 are preferred, the paired layers of GaN/AlGaN can have a composition of Al_{X}In_{Y}Ga_{Z}N, where x+y+z=1 (including 0% In and/or 0% Al). The embodiment of the invention shown in FIG. 3 has three additional pairs of GaN/AlGaN layers, i.e., second GaN layer 14′/second AlGaN layer 16′, third GaN layer 14″/third AlGaN layer 16″, and fourth GaN layer 14′″/fourth AlGaN layer 16′″. More or less of the paired buffer/barrier layers may be provided to accordingly modify the 2DEG density in the channel underneath the barrier layer 16. Each AlGaN layer 16-16′″ of the stack has a lower GaN concentration than the immediately underlying GaN layer 14-14′″. The layers of the stack have a thickness of approximately 1 nm-20 nm.

As illustrated in FIGS. 3-5, in the preferred embodiment of the invention, the layers 14′-14′″ and 16′-16′″ are respectively aligned or substantially aligned on the side closest to the source in a pairwise manner, such that, as shown layer 14′ and layer 16′ are aligned on the source side, and layers 14″, 16″, and layers 14′″, 16′″ are likewise aligned on the source side. The aligned layers 14′, 16′ extend a first distance from the source, the aligned layers 14″, 16″ extend a second distance from the source which is greater than the first distance, and the aligned layers 14′″, 16′″ extend to a third distance from the source, which is greater than the second distance, resulting in a stepped topology. The layers 14-14′″ and 16-16′″ are all aligned with each other and in contact with the drain contact 20. Thus, as shown in FIGS. 3-5, a number of stepped segments 40, 42, 44 and 46 of increasing height are defined by the buffer layer 14, the barrier layer 16, and by the layers 14′-14′″ and 16′-16′″. More or less stepped segments may be formed depending on the intended application, as described more fully below. It should be understood that the vertical surfaces may not be perfectly vertical, but can have rounded and/or tapered portions producing layers. Additional patterns are contemplated to provide the varied thicknesses including a sloped pattern across the one or more column III nitride layers.

As a result of the GaN/AlGaN interface and the resulting 2DEG created by each pair of layers, each of the segments 40, 42, 44, 46 produces a progressively increasing number of free electrons. The free electrons created in the 2DEGs of each of the segments 42, 44 and 46 migrate down to the 2DEG channel at the top of GaN channel layer 14, such that the 2DEG channel has a higher density of free electrons near the drain and a lower density of electrons near the gate. The height of the segments (i.e., the vertical distance that the free electrons must travel to reach the 2DEG channel) is also a factor. Thus, the thicknesses of the pairs of layers 14′/16′, 14″/16″ 14′″/16′″ may also be varied to vary the density of electrons in the 2DEG channel.

As illustrated in FIGS. 3-5, the gate may be positioned on any of the segments 40, 42, 44, 46 (i.e., on any of the levels above the first barrier 16), and, as described more fully below, the V_{TH} and mode (enhancement mode/depletion mode) of the device is dependent on the height of the gate (i.e., the vertical distance between the gate and the 2DEG channel).

In the transistor 100 illustrated in FIG. 3, the gate 22 is positioned at a first level on the first segment 40, directly on first barrier layer 16. Segment 40 produces the lowest density of electrons in the channel 2DEG, such that the p-doped material 26 of the gate depletes the free electrons in the underlying 2DEG channel at zero voltage. A positive voltage must be applied to the gate 100 in order to replenish the electrons in the 2DEG underneath the gate, and produce a conducting path of electrons between the source contact 18 and the drain contact 20. Thus, the device operates in enhancement mode (normally-off). The V_{TH} of the device (the positive voltage needed to replenish the electrons in the 2DEG to turn the device on) is highest in this embodiment because 2DEG channel has the lowest electron density.

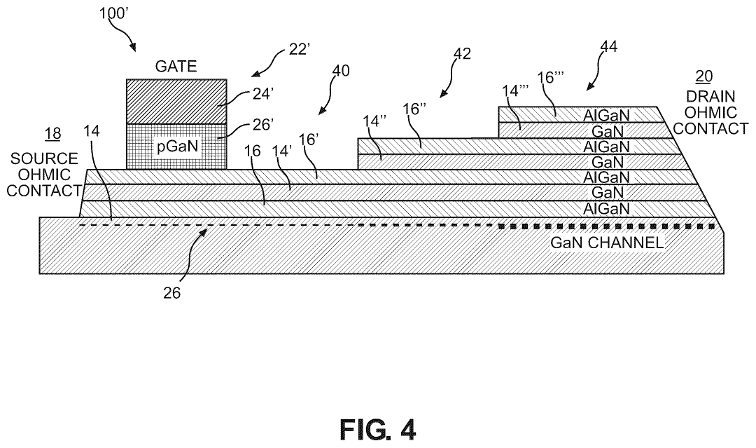

In the transistor 100′ illustrated in FIG. 4, the gate 22 is formed on the second barrier layer 16′ (i.e., at the same level as the second segment 42 of FIG. 3). The V_{TH} of the device is less positive in this embodiment because the interface of the second buffer layer 14′ and the second barrier 16′ produces free electrons, resulting in a greater density of electrons in the 2DEG channel under the gate than in device of FIG. 3.

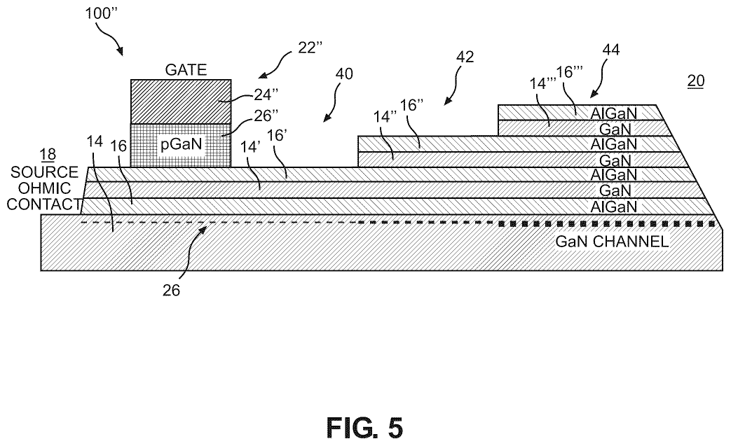

In the transistor 100″ illustrated in FIG. 5, the gate is positioned at the second level directly on the second barrier 16′ (as in the device of FIG. 4). However, in transistor 100″, at least one of the underlying buffer layers 14′, 14″ 14′″ and/or barrier layers 16′, 16″, 16′″ is doped with an n-type dopant, such as silicon or geranium, at a concentration of 1×10¹⁶ cm⁻³ to 1×10²⁰ cm⁻³, producing an increased number of free electrons. The increased number of free electrons increases the density of the 2DEG underneath the gate 22″ and decreases the threshold voltage of the transistor. If the number of electrons in the 2DEG is greater than can be depleted by the p-doped GaN layer 26″ at zero voltage, device 100″ operates in depletion mode, and a negative voltage must be applied to the p-doped GaN layer 26″ to deplete the 2DEG underneath the gate 22 and interrupt the current path between the drain and source.

An integrated circuit may be formed with individual transistors have different threshold voltages using the gate positioning and/or doping discussed above. Thus, the integrated circuit may have one or more transistors with a first V_{TH} (the gate being formed directly on the first barrier 16 of the first segment 40 as in FIG. 3), one or more transistors with a second V_{TH} (the gate being formed on the second barrier 16′ of the second segment 42 as in FIG. 4), and/or one or more transistors with a third V_{TH} (the gate being formed directly on the third barrier 16″ of the third segment 44), where the first V_{TH} is higher than the second V_{TH}, and the second V_{TH} is higher than the third V_{TH}. Alternatively or in addition, an integrated circuit may be formed with both enhancement mode and depletion mode transistors such as in the embodiments of FIG. 3 (enhancement mode) and FIG. 5 (depletion mode) described above.

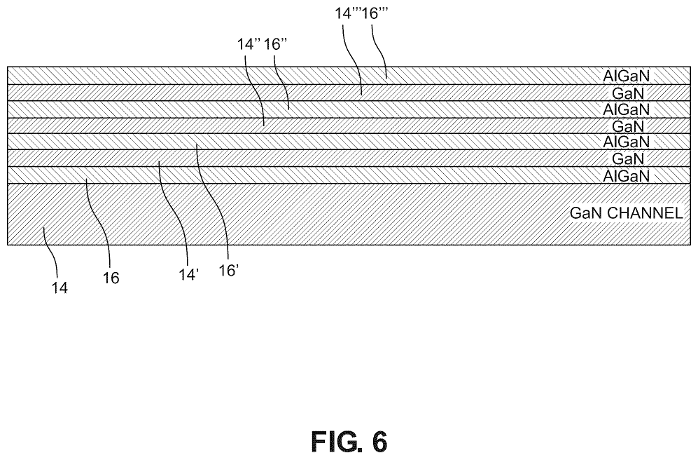

FIGS. 6-12 illustrate a method of producing a transistor according to the present invention. The fabrication process starts with growing or depositing the transition layers 12 on the substrate 10, as illustrated in FIG. 1. As illustrated in FIG. 6, a plurality of GaN layers 14-14′″ and AlGaN layers 16-16′″ are then deposited or grown on the transition layers 12.

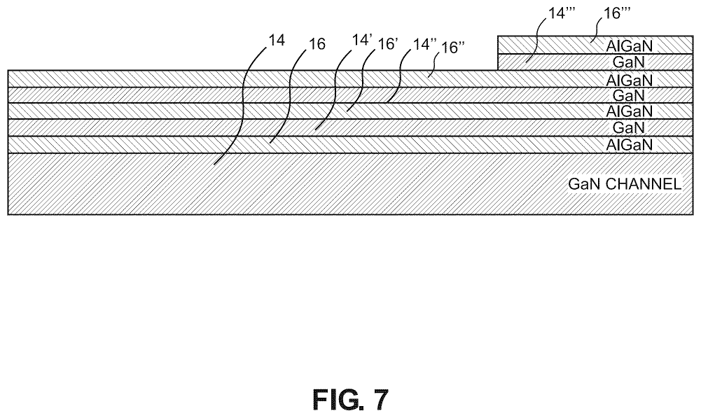

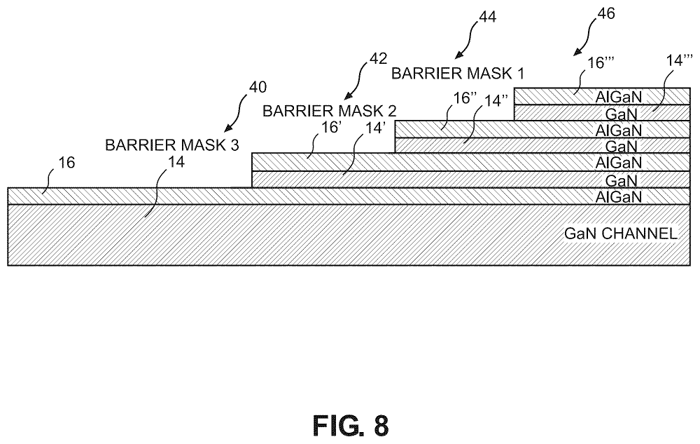

As illustrated in FIGS. 7 and 8, the varied thickness of the barrier layer is produced by etching layers 14′-14′″ and 16′-16′″ using photolithographic techniques. The thickness of the third segment 44 may be produced by etching the AlGaN layer 16′″ and the GaN layer 14′″ at a first distance from the source, exposing a segment of the AlGaN layer 16″. The thickness of the second segment 42 may be produced by etching the AlGaN layer 16″ and the GaN layer 14″ starting at a second distance from the source, exposing a segment of the AlGaN layer 16′. The thickness of the first segment 40 may be produced by etching the AlGaN layer 16′ and the GaN layer 14′ starting at a third distance from the source, exposing a segment of the AlGaN layer 16. Thus, the resultant structure is a stepped pattern of GaN and AlGaN layers, as discussed herein.

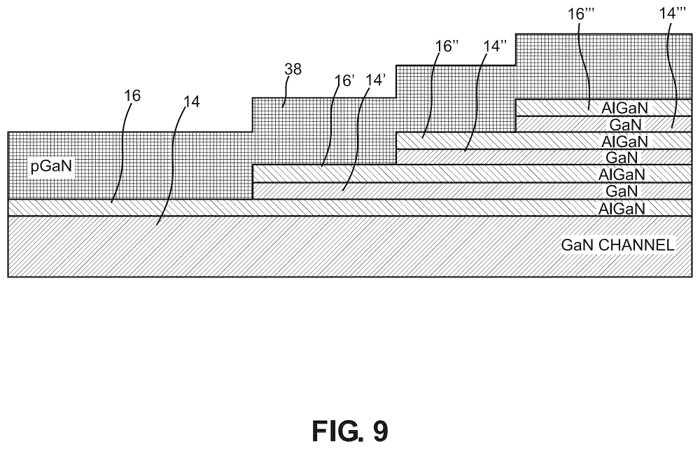

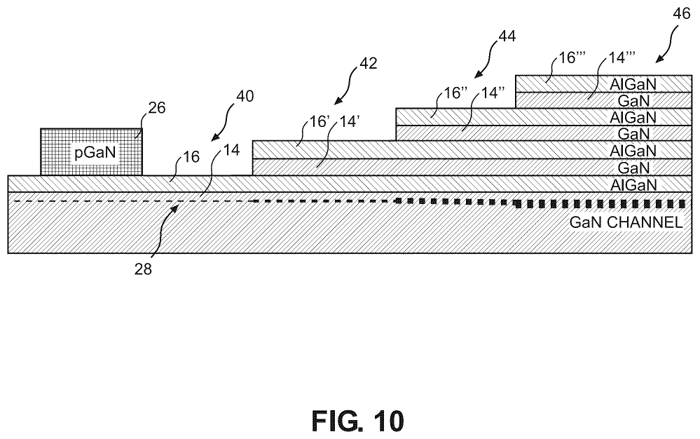

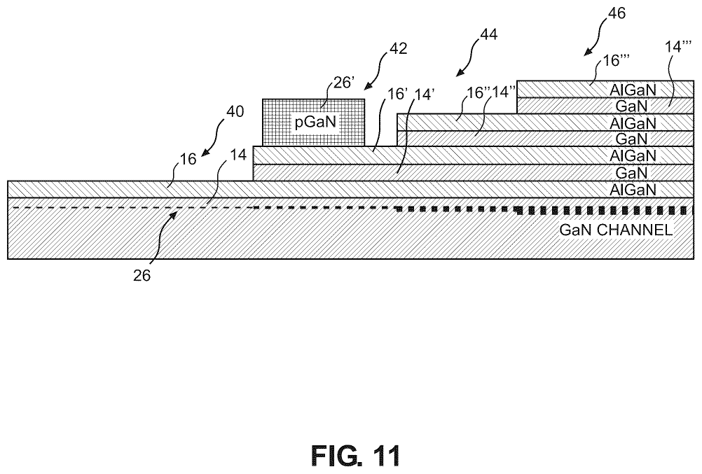

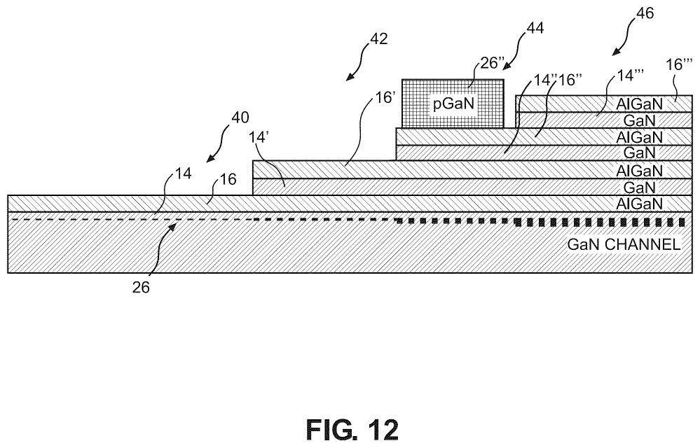

As illustrated in FIG. 9, a precursor layer 38 of the p-type GaN material 26 may be grown on the exposed segments of barrier layers 16, 16′, 16″, 16′″. The precursor layer 38 may be patterned and etched to form p-type GaN material layer 26 for the gate 22 on any of the levels of the transistor. For example, as illustrated in FIG. 10, the gate 22 may be formed by patterning and etching the precursor layer 38 on the AlGaN 16 of first segment 40 to produce the device of FIG. 3. Alternatively, as illustrated in FIG. 11, the gate 22′ may be formed by patterning and etching the precursor layer 38 on the AlGaN layer 16′ of the second segment 42 to produce the device of FIG. 4. Alternatively, as illustrated in FIG. 12, the gate may be formed by patterning and etching the precursor layer 38 on the AlGaN 16″ of the third segment 44. The gate contact 24 is patterned and etched over the p-type GaN material layer 26 to form the gate 22. The patterning and etching of the gate contact 24 may be performed with the patterning and etching of the p-type GaN material 26 in a self-aligned technique, as disclosed in U.S. Pat. Nos. 8,404,508 and 9,748,347, the entire disclosures of which are incorporated herein by reference. The source contact 18 and the drain contact 20 may then be patterned and etched.

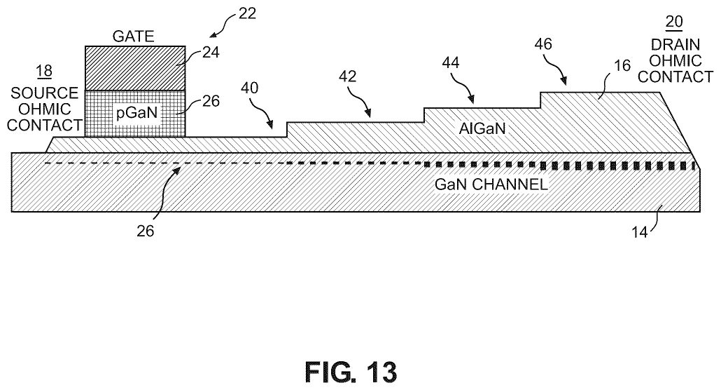

FIG. 13 illustrates a fourth embodiment of a transistor 200 of the present invention. In this embodiment, the stepped profile of the barrier layer as described above with respect to the first, second and third embodiments is formed of a single AlGaN layer 16 of varying thicknesses, rather than stacked GaN/AlGaN layers of varying heights. In the fourth embodiment of the invention shown in FIG. 13, the gate 22 is formed on the first segment 40, but alternatively, as in the first, second and third embodiments, the gate can be formed on any of the segments, 40, 42, 44 or 46, to adjust the V_{TH} of the device. Similarly, as in the previously described embodiments, the AlGaN layer 16 can be doped with an n-type material (silicon or germanium, for example) to increase the 2DEG density or tune the threshold voltage of the transistor.

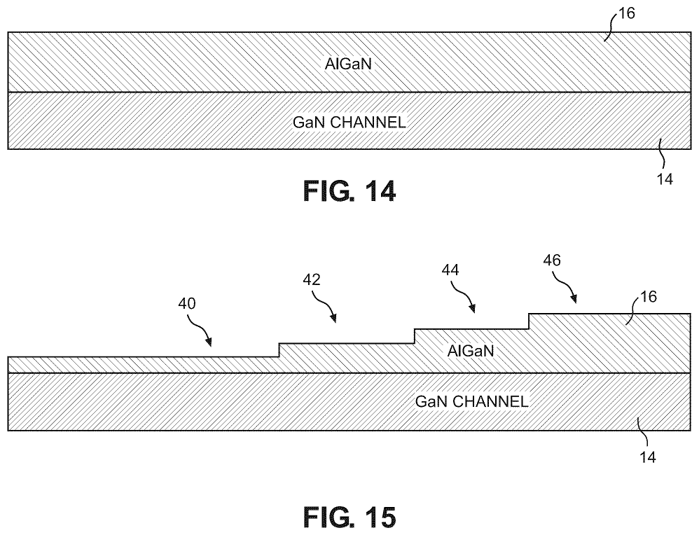

The method of forming the fourth embodiment of the present invention is shown in FIGS. 14-16. As with the first three embodiments, the fabrication process starts with growing or depositing the transition layers 12 on the substrate 10, as illustrated in FIG. 1. GaN buffer layer 14 is deposited on the transition layers 12, and a AlGaN barrier layer 16 is be deposited on the buffer layer 14. The barrier layer 16 as initially deposited is relatively thick (approximately 20 nm to 30 nm) as compared to a typical barrier layer thickness (10-15 nm) of the first three embodiments. Barrier layer 16 preferably comprises approximately 25% Al, as is typical. The thickness of the barrier layer 16 and the percentage of Al can vary and trade off with each other, i.e., thicker low Al percentage barrier layer is similar in function to a thinner high Al percentage barrier layer.

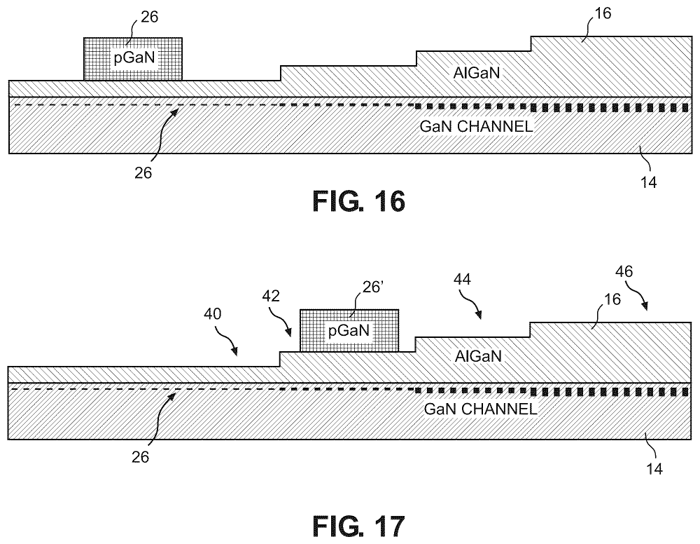

As illustrated in FIG. 16, the barrier layer 16 is etched to form the segments 40-46 of multiple heights. Since the barrier layer 16, although relatively thick compared to a typical barrier layer, is still a very thin layer, atomic layer etching (ALE), with extremely fine depth control, is preferably employed to form the structure. As shown in FIG. 16, the p-GaN material 26 of the gate can be positioned on the first segment 40, but it can also be grown, patterned and etched on any of the other segments 42, 44, 46 to vary the V_{TH} of the device, as described above.

Accordingly, the transistor of present invention, as in the above-described embodiments, includes a multi-layer/multi-thickness barrier layer formed of segments of progressively increasing thickness between the gate and drain to progressively increase the 2DEG density in the channel from gate to drain. The GaN gate can be formed on the base barrier layer to produce an enhancement mode device with a positive threshold voltage. By forming the gate over a thicker segment of the barrier layer, a GaN transistor with a less positive threshold voltage, or a depletion mode transistor with a negative threshold voltage, can be produced. The varying thickness of barrier layer advantageously provides the additional advantage of being able to customize the threshold voltage of the device.

Advantageously, in accordance with the present invention, an integrated circuit on a single substrate may be provided with transistors having different threshold voltages, or even depletion mode transistors having negative threshold voltages.

While systems and methods have been described in connection with the various embodiments of the various FIGures, it will be appreciated by those skilled in the art that changes could be made to the embodiments without departing from the broad inventive concept thereof. It is understood, therefore, that this disclosure is not limited to the particular embodiments disclosed, and it is intended to cover modifications within the spirit and scope of the present disclosure as defined by the claims.

What is claimed is:

1. A column III nitride transistor comprising:
a substrate;
a buffer layer positioned above the substrate, wherein the buffer layer comprises a column III nitride material;
a barrier layer positioned immediately above the buffer layer, wherein the barrier layer comprises a column III nitride material;
a channel comprising a conductive two-dimensional electron gas (2DEG) formed in the buffer layer near a junction of the buffer layer and the barrier layer;
one or more column III nitride material layers above the barrier layer, wherein a first segment and a second segment are defined by the barrier layer and/or the one or more column III nitride material layers above the barrier layer, wherein the first segment has a first thickness and the second segment has a second thickness, the first thickness being less than the second thickness, wherein the number of free electrons in the first segment is lower than the number of free electrons in the second segment, such that the 2DEG in the channel under the first segment has a lower density of electrons than the 2DEG in the channel under the second segment; and
a gate, a source, and a drain, each positioned above the buffer layer, wherein the gate is positioned over the barrier layer between the source and the drain.

2. The transistor of claim 1, wherein the first segment is closer to the source than the second segment.

3. The transistor of claim 1, wherein the one or more column III nitride material layers above the barrier layer comprise Al_{X}In_{Y}Ga_{Z}N, where x+y+z=1.

4. The transistor of claim 1, wherein the one or more column III nitride material layers above the barrier layer comprise paired layers of GaN and AlGaN.

5. The transistor of claim 2, wherein the transistor has a first threshold voltage with the gate positioned on the first segment, and the transistor has a second threshold voltage lower than the first threshold voltage with the gate positioned on the second segment.

6. The transistor of claim 5, wherein the paired layers of GaN and AlGaN are doped with an n type dopant to increase the density of electrons in the 2DEG and decrease the threshold voltage of the transistor.

7. The transistor of claim 6, wherein the threshold voltage is negative, and the transistor is a depletion mode transistor.

8. An integrated circuit comprising a plurality of the transistors of claim 1.

9. The integrated circuit of claim 8, wherein at least one of the transistors has a first threshold voltage and at least one of the transistors has a second threshold voltage lower than the first threshold voltage.

10. A column III nitride transistor comprising:
a substrate;
a buffer layer positioned above the substrate, wherein the buffer layer comprises a column III nitride material;
a barrier layer positioned above the buffer layer, wherein the buffer layer comprises a column III nitride material;
a channel comprising a conductive two-dimensional electron gas (2DEG) formed in the buffer layer near a junction of the buffer layer and the barrier layer;
wherein the barrier layer has a first segment with a first thickness and a second segment with a second thickness, wherein the first thickness is less than the second thickness, wherein the number of free electrons in the first segment is lower than the number of free electrons in the second segment, such that a 2DEG density in the channel under the first segment is lower than a 2DEG density in the channel under the second segment; and
a gate, a source, and a drain, each positioned above the buffer layer, wherein the gate contact is positioned over the barrier layer between the source and the drain.

11. The transistor of claim 10, wherein the first segment is closer to the source than the second segment.

12. The transistor of claim 10, wherein the barrier layer comprises AlGaN.

13. The transistor of claim 10, wherein the transistor has a first threshold voltage with the gate positioned on the first segment, and the transistor has a second threshold voltage lower than the first threshold voltage with the gate positioned on the second segment.

14. The transistor of claim 12, wherein the barrier layer is doped with an n type dopant to increase the density of electrons in the 2DEG and decrease the threshold voltage of the transistor.

15. An integrated circuit comprising a plurality of the transistors of claim 10.

16. The integrated circuit of claim 15, wherein at least one of the transistors has a first threshold voltage and at least one of the transistors has a second threshold voltage lower than the first threshold voltage.
